(19) United States
(12) Patent Application Publication
(10) Pub. No.: US 2005/0260789 A1
(43) Pub. Date: Nov. 24, 2005

(54) Method and system for applying an adhesive substance on an electronic device

(75) Inventors: Mark Gerald M. Cruz, Baguio City (PH); Jinky D. Cruz, Baguio City (PH); Jerry G. Cayabyab, Baguio City (PH)

Correspondence Address: TEXAS INSTRUMENTS INCORPORATED, P O BOX 655474, M/S 3999, DALLAS, TX, 75265, US

(73) Assignee: Texas Instruments Incorporated

(21) Appl. No.: 10/851,552

(22) Filed: May 21, 2004

(51) Int. Cl. H01L 21/44; H01L 23/02; H01L 21/50; H01L 21/48

(52) U.S. Cl. 438/106

(57) ABSTRACT

According to one embodiment of the invention, a system for applying an adhesive substance to an electronic device having a region designated to be coupled to another device is provided. The region has a first shape defined by a first boundary. The system includes a tube having an open end. The system also includes a nozzle having an opening coupled to the open end of the tube. The opening has a second shape that is approximately the same as the first shape.

### TECHNICAL FIELD OF THE INVENTION

This invention relates generally to electronics and more particularly to a method and system for applying an adhesive substance on an electronic device.

### BACKGROUND OF THE INVENTION

Adhesive substances are used in many instances to couple various electronic devices in electronic products. For example, in manufacturing a ball grid array, a die is attached to a substrate using epoxy before interconnecting the die to the conducting tracks of the substrate. The use of an adhesive substance for coupling a die to a substrate may lead to problems, especially when the die is considered large. For example, the epoxy coverage between the die and the substrate may be insufficient. In another example, air may be trapped in the epoxy. Such problems may result in package cratering and epoxy voiding, which may be undesirable an electronic product.

### SUMMARY OF THE INVENTION

According to one embodiment of the invention, a system for applying an adhesive substance to an electronic device having a region designated to be coupled to another device is provided. The region has a first shape defined by a first boundary. The system includes a tube having an open end. The system also includes a nozzle having an opening coupled to the open end of the tube. The opening has a second shape that is approximately the same as the first shape.

Some embodiments of the invention provide numerous technical advantages. Other embodiments may realize some, none, or all of these advantages. For example, according to one embodiment, adhesive coverage is improved for an electronic device by dispensing the adhesive substance through an opening of a nozzle that has approximately the same shape as, but slightly smaller than, the surface area of an electronic device that is designated to be coupled to another surface. According to another embodiment, the transfer of the adhesive substance is improved by using a nozzle that has a non-vertical side wall.

Other advantages may be readily ascertainable by those skilled in the art.

### BRIEF DESCRIPTION OF THE DRAWINGS

Reference is now made to the following description taken in conjunction with the accompanying drawings, wherein like reference numbers represent like parts, in which:

FIGS. 1A-1C are schematic diagrams illustrating a process of coupling electronic devices using an adhesive substance;

FIG. 2 is a schematic diagram illustrating one embodiment of a dispenser system that may be used in conjunction with the process shown in FIGS. 1A-1C;

FIG. 3A is a front view of one embodiment of a nozzle of the dispenser system shown in FIG. 2;

FIG. 3B is a side view of one embodiment a nozzle of the dispenser system shown in FIG. 2;

FIG. 3C is a perspective view of one embodiment of a nozzle of the dispenser system shown in FIG. 2;

FIG. 3D is a bottom view of one embodiment of a nozzle of the dispenser system shown in FIG. 2;

FIG. 4A is a front view of one embodiment a nozzle of the dispenser system shown in FIG. 2;

FIG. 4B is a side view of one embodiment of a nozzle of the dispenser system shown in FIG. 2;

FIG. 4C is a perspective view of one embodiment of a nozzle of the dispenser system shown in FIG. 2; and

FIG. 5 is a block diagram illustrating one embodiment of a method for applying an adhesive substance on an electronic device.

### DETAILED DESCRIPTION OF EXAMPLE EMBODIMENTS OF THE INVENTION

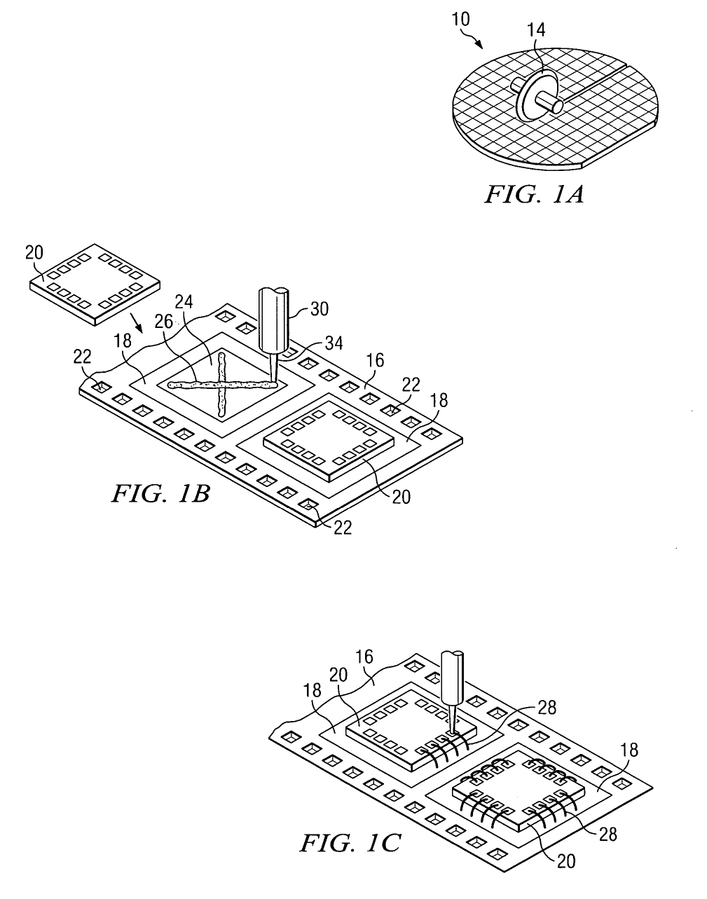

Embodiments of the invention are best understood by referring to FIGS. 1A through 5 of the drawings, like numerals being used for like and corresponding parts of the various drawings.

FIGS. 1A-1C are schematic diagrams illustrating an example process of coupling electronic devices using an adhesive substance. FIGS. 1A-1C are described jointly. Referring to FIG. 1A, a wafer 10 is singulated into a plurality of die (not explicitly shown in FIG. 1A) using a mechanical saw 14. Referring to FIG. 1B, die 20 resulting from performing the step shown in FIG. 1A are coupled with their respective substrates 18. Substrates 18 are positioned on a substrate clip 16 attached to substrate boats 22, as shown in FIG. 1B. To couple die 20 with substrate 18, an adhesive substance 26 is applied on an area 24 that is designated to be coupled to die 20. Adhesive substance 26 is applied using a dispenser 30 having a nozzle 34. After adhesive substance 26 is applied to area 24, die 20 is positioned over adhesive substance 26 and area 24 of substrate 18. Then die 20 is pressed into adhesive substance 26 and cured to form an attachment between die 20 and substrate 18. Referring to FIG. 1C, after die 20 are coupled to their respective substrates 18, connections 28 between the connectors (not explicitly shown in FIG. 1C) of die 20 and conducting tracks (not explicitly shown in FIG. 1C) of substrate 18 are formed using a suitable process, such as wire bonding.

An adhesive substance, such as epoxy, may be provided on a substrate using different methods. One such method is referred to as a “writing dispense method.” The writing dispense method is implemented using a dispenser tool that has a needle-like nozzle. The dispenser tool is manipulated to “write” an “X” pattern on the substrate using the adhesive substance. Another available method is referred to as a “stamping dispense method.” The stamping dispense method is implemented using a dispenser tool that has a bundle of needle-like nozzles that are arranged in a particular pattern—usually in an “X” formation. When an appropriate amount of the adhesive substance is dispensed from all of the nozzles in the bundle, the adhesive substance is provided on the substrate in a corresponding “X” formation. A die is positioned over the “X” pattern of adhesive substance, pressed against the substrate, and cured. The above-identified methods of applying an adhesive substance for coupling electronic devices may result in inconsistent adhesive coverage and/or air entrapment between a die and a substrate, which may be undesirable.

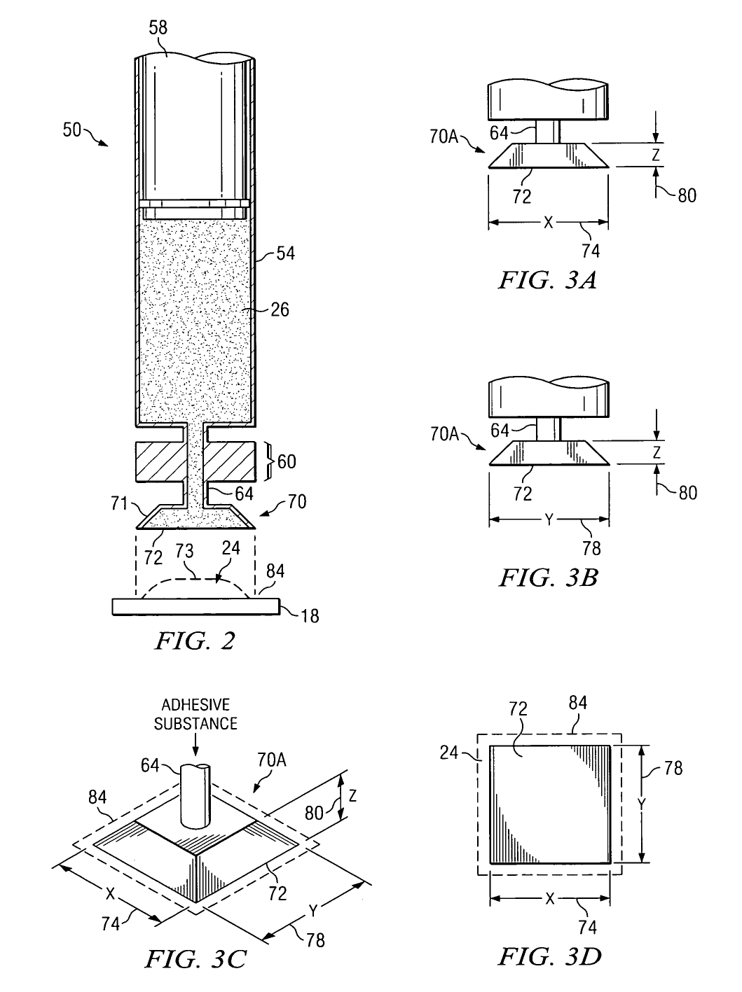

According to one embodiment of the invention, a system and method for applying an adhesive substance for coupling electronic devices are provided. In one embodiment of the invention, an improved level of adhesive coverage is provided by using a nozzle that defines an opening having approximately the same shape as, but a smaller size than, an area of an electronic device that is designated to be coupled with another electronic device. In another embodiment, the probability of air entrapment is reduced by providing a mound of adhesive substance on an area of an electronic device that is designated to be coupled with another electronic device. The footprint of the mound of adhesive has approximately the same shape as, but a slightly smaller size than, the designated area. In another embodiment, the transfer of an adhesive substance is improved by dispensing the adhesive substance using a nozzle that has a non-vertical side wall. Additional details of example embodiments of the invention are described below in greater detail in conjunction with FIGS. 2 through 5.

FIG. 2 is a schematic diagram illustrating one embodiment of a dispenser system 50 that may be used to dispense an adhesive substance 26 to couple electronic devices. System 50 includes a tube 54, a piston 58, a connector 60 having a neck 64, and a nozzle 70. Tube 54 is attached to nozzle 70 through neck 64 of connector 60. Piston 58 is positioned inside tube 54 and operable to move along the length of tube 54 to move any adhesive substance 26, such as epoxy, through connector 60, neck 64, and into an inner area defined by nozzle 70. For illustrative purposes, epoxy is used as an example of adhesive substance 26 to describe some embodiments of the invention; however, any suitable adhesive substance may be used as adhesive substance 26.

As shown in FIG. 2, nozzle 70 has a side wall 71 that defines an opening 72. According to one embodiment of the invention, opening 72 has approximately the same shape as, but a slightly smaller size than, an area of an electronic device that is designated to be coupled to another electronic device using an adhesive substance. Such an area is referred to as a “target area.” In an example where the entire rectangular face of die 20 shown in FIG. 1B is designated to be coupled to substrate 18 using epoxy 26, the entire rectangular face of die 20 is referred to as a target area. Area 24 of substrate 18 shown in FIG. 1B is a target area of substrate 18 because area 24 is designated to be coupled to the rectangular face of die 20. Thus, the respective target areas of die 20 and substrate 18 are identical in both shape and size. Although the entire rectangular face of die 20 is used as an example of a target area of an electronic device, a target area may have a variety of shapes and sizes depending on the particular design specifications of an electronic device. Further, a target area does not necessarily occupy an entire surface area of a device. For example, a circular portion of the rectangular face of die 20 may be designated as a target area.

Referring to FIG. 2, in one embodiment, opening 72 is defined in the same rectangular shape and has a size that is slightly smaller than the rectangular target area of die 20. The height of nozzle 70 is optimized in view of the length and the width of opening 72 to dispense a suitable amount of epoxy 26 so that when the dispensed epoxy 26 is pressed between die 20 and substrate 18, a predetermined percentage of the target area of die 20 is covered by epoxy 26. In one embodiment, the length and the width of nozzle 70 is optimized in view of a particular height of nozzle 70 to dispense a suitable amount of epoxy 26 SO that when the dispensed epoxy 26 is pressed between die 20 and substrate 18, a predetermined percentage of the target area of die 20 is covered by epoxy 26. In one embodiment, the predetermined percentage is at least 95 percent; however, the predetermined percentage may be less than 95 percent. An epoxy coverage of at least ninety-five percent is desirable in some electronic devices to achieve a predetermined level of physical stability and heat transfer. In one embodiment, other percentages of epoxy coverage is used as a predetermined percentage. For example, the predetermined percentage of epoxy coverage may be approximately 100 percent, approximately 95 percent, or any other percentage or a range of percentages that meets the particular design specifications of an electronic device.

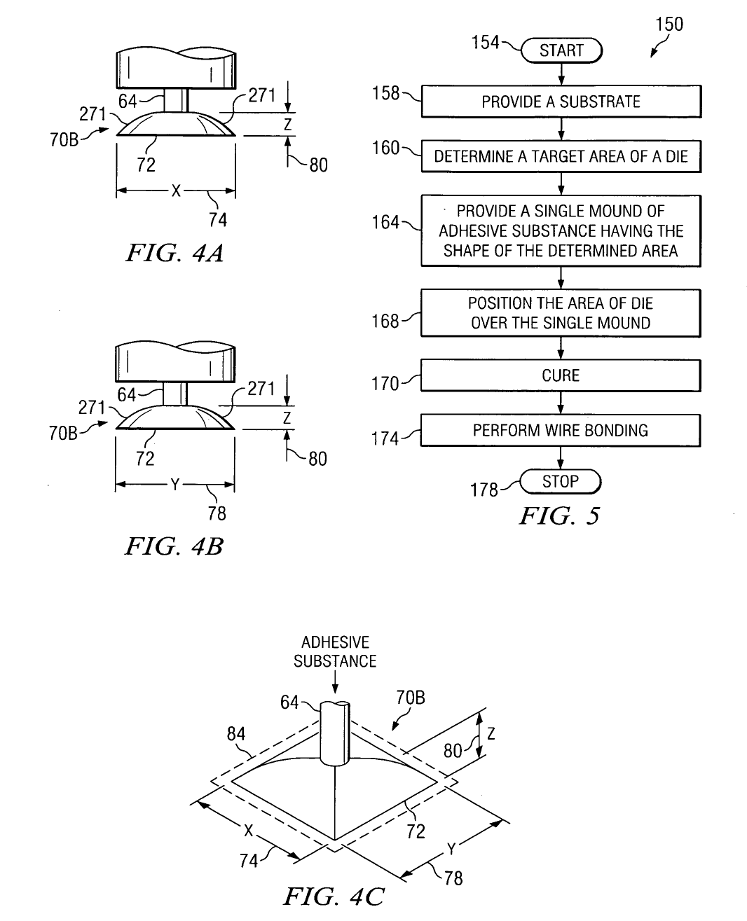

In one embodiment, side wall 71 of nozzle 70 is non-vertical. For example, as shown in FIG. 2, side wall 71 is outwardly flared. In some embodiments, this improves the transfer of epoxy 26 by reducing epoxy accumulation in any corners that may be present in nozzle 70. Further, a non-vertical side wall 71 reduces the friction between side wall 71 and epoxy 26 as nozzle 70 is lifted off of substrate 18 to leave behind a mound 73 of epoxy 26. Because of the reduced friction, a higher percentage of epoxy 26 is transferred from nozzle 70 to substrate 18. Additional details concerning the physical dimensions of nozzle 70 are provided below in conjunction with FIGS. 3A-4C.

In operation, nozzle 70 of system 50 is placed over target area 24 that is defined by boundary 84. Target area 24 is identical in shape and size as the target area of die 20, which, in this example, is the entire rectangular face of die 20. After nozzle 70 is lowered to a height that is suitable for dispensing epoxy 26, piston 58 moves along tube 54 to fill an inner chamber that is formed between nozzle 70 and target area 24 of substrate 18. Once the inner chamber defined by target area 24 and nozzle 70 is filled with epoxy 26, nozzle 70 of system 50 is lifted from area 24, leaving mound 73 of epoxy 26 within boundary 84 of target area 24. In one embodiment, because opening 72 has the same shape as the target area 24 (and thus the same size as the target area of die 20) but slightly smaller than the target area 24, the footprint of mound 73 is approximately the same shape as target area 24 but slightly smaller than target area 24. After mound 73 is formed using system 50, die 20 is positioned over mound 73 and area 24. Once die 20 is pressed against area 24, mound 73 spreads between the respective target areas of die 20 and substrate 18 to cover an area that exceeds the size of opening 72. The spread mound 73 is cured to finalize the coupling process.

FIGS. 3A and 3B are front and side views, respectively, of one embodiment of a nozzle 70A that may be used in conjunction with system 50 of FIG. 2. FIGS. 3A and 3B are described jointly. As shown in FIG. 3A, nozzle 70A comprises a width 74 and a height 80. As shown in FIG. 3B, nozzle 70A comprises a length 78. In one embodiment where at least a 95 percent adhesive coverage of a target area of die 20 is desired, width 74 is approximately 0.1 millimeter less than a corresponding width of the target area, length 78 is approximately 0.1 millimeter less than the corresponding length of the target area, and height 80 is approximately 120-130 micrometers. In one embodiment where at least a 95 percent adhesive coverage of a target area of die 20 is desired, and the target area has a width of at least 8 millimeters and a length of at least 8 millimeters, width 74 is approximately 0.1 millimeter less than a corresponding width of the target area, length 78 is approximately 0.1 millimeter less than the corresponding length of the target area, and height 80 is approximately 120-130 micrometers. In one embodiment, height 80 is reduced as the dimensions of a target area increase.

As shown in FIG. 3B, nozzle 70A has a trapezoidal side profile. This is advantageous in some embodiments because the non-vertical side wall 71 of nozzle 70A reduces the friction between side wall 71 and epoxy 26, which results in a more efficient transfer of epoxy 26 when nozzle 70A is lifted off of substrate 18.

FIG. 3C is a perspective diagram of nozzle 70A. FIG. 3D is a bottom view of nozzle 70A showing opening 72. FIGS. 3C and 3D are described jointly. As shown in FIGS. 3C and 3D, opening 72 of nozzle 70A has approximately the same shape as target area 24, which is defined by boundary 84 and mirrors the target area of an electronic device, such as die 20. An opening of a nozzle having the same shape as a target area is advantageous in some embodiments because the probability of air entrapment is reduced for the adhesive substance dispensed from such an opening. In one embodiment, width 74 and length 78 are approximately 0.1 millimeter less than the corresponding width and the length of target area 24 defined by boundary 84, and height 80 is approximately 120-130 micrometers. This is advantageous in some embodiments because a mound of an adhesive substance formed from such an embodiment of nozzle 70A results in at least 95 percent epoxy coverage of the respective target areas of the electronic devices. In one embodiment, if target area 24 defined by boundary 84 has a width of at least 8 millimeters and a length of at least 8 millimeters, width 74 and length 78 are approximately 0.1 millimeter less than the corresponding width and the length of target area 24 defined by boundary 84, and height 80 is approximately 120-130 micrometers.

Although the shape of opening 72 is rectangular because a rectangular target area is used as an example to describe some embodiments of the invention, the shape of opening 72 may be in any shape. For example, if the target area of die 20 is circular, then opening 72 is also defined in a circular shape. In such an embodiment, if at least a 95 percent adhesive coverage is desired, the diameter of circular opening 72 is approximately 0.1 millimeter less than the corresponding diameter of the circular target area of die 20. The height is approximately 120-130 micrometers. In one embodiment, opening 72 has a size and shape such that when nozzle 70A is positioned within a target area, the boundary that defines opening 72 is separated from the boundary that defines the target area by approximately 0.05 millimeter.

FIGS. 4A-4C are front, side, and perspective views, respectively, of one embodiment of a nozzle 70B that may be used in conjunction with system 50 shown in FIG. 2. FIGS. 4A-4C are described jointly. As shown in FIGS. 4A and 4B, nozzle 70B has the same width 74, length 78, and height 80 as nozzle 70A shown in FIGS. 3A-3C. In one embodiment, as shown in FIGS. 4A-4C, nozzle 70B has a side wall 271 that defines a parabolic side profile. This is advantageous in some embodiments because the non-vertical side wall 71 of nozzle 70A reduces the friction between side wall 71 and epoxy 26, which results in a more efficient transfer of epoxy 26 when nozzle 70B is lifted off of substrate 18. Further, the number of corners in nozzle 70B is reduced, which lowers the probability of epoxy accumulation. In one embodiment, opening 72 has a size and shape such that when nozzle 70B is positioned within a target area, the boundary that defines opening 72 is separated from the boundary that defines the target area by approximately 0.05 millimeter.

In one embodiment, width 74, length 78, and height 80 of nozzles 70A and 70B shown in FIGS. 3A-4C are optimized depending on the type of the adhesive substance used, the size and shape of a target area of an electronic device, and any other appropriate factors to achieve an acceptable level of adhesive coverage for an electronic device. In one embodiment, width 74 and length 78 are such that opening 72 of nozzle 70A or nozzle 70B has the same shape as a target area, but is proportionally smaller by a predetermined percentage. For example, opening 72 is approximately 95 percent of the size of the target area, or any other suitable percentage depending on the desired level of adhesive coverage of the target area. The acceptable level of adhesive coverage depends on the particular specification of the electronic products in which the electronic devices are used. In one embodiment, the acceptable level of coverage is at least approximately 95 percent.

FIG. 5 is a method 150 for applying an adhesive substance on an electronic device. For illustrative purposes, the features described in FIGS. 1A through 4C are used to describe one embodiment of method 150. However, any suitable device or combination of devices may be used to implement method 150.

Method 150 starts at step 154. At step 158, substrate 18 is provided. At step 160, a target area of die 20 is determined. In one embodiment, a rectangular face of die 20 is designated as the target area of die 20; however, any portion of any electronic device having any shape or any size may be designated as the target area. At step 164, mound 73 of epoxy 26 having a footprint in the shape of the target area is provided using system 50 of FIG. 2. In one embodiment, the footprint of mound 73 of step 164 is slightly smaller than the target area of step 160, which accounts for the spreading of the epoxy mound that may occur when die 20 is pressed against substrate 18. In one embodiment, the footprint of mound 73 of step 164 is proportionally smaller than the target area of step 160 by approximately five percent. In one embodiment, the mound of step 164 is provided using nozzles 70A or 70B; however, any device that is operable to form mound 73 may be used to perform step 164.

At step 168, die 20 is placed over epoxy mound 73. At step 170, epoxy mound 73 is cured. At step 174, a wire bonding process is performed to make suitable electronic connections between die 20 and substrate 18. In some embodiments, steps 168, 170, and 174 may be omitted. Method 150 stops at step 178.

Although some embodiments of the present invention have been described in detail, it should be understood that various changes, substitutions, and alterations can be made hereto without departing from the spirit and scope of the invention as defined by the appended claims.

1. A system for coupling a die to a substrate, the die having a rectangular footprint, a first width, and a first length, the system comprising:
a first tube having a tube length and a first end, the first end having a first cross sectional area;
a second tube coupled to the first end of the first tube, the second tube including a second end positioned opposite from the first end and a second cross sectional area that is smaller than the first cross sectional area;
a nozzle including a third end coupled to the second end of the second tube and an outwardly flaring rectangular opening defined at approximately 120 millimeters to 130 millimeters away from the third end, the third end having a third cross sectional area that is larger than the second cross sectional area of the second tube, wherein the rectangular opening comprises a second width approximately 0.1 millimeter less than the first width; and
a piston positioned in the first tube and operable to move a viscous adhesive substance disposed in the first tube along the tube length of the first tube, through the second tube, and into the nozzle.

2. The system of claim 1, wherein the nozzle comprises a side disposed between the third end and the rectangular opening, the side having a parabolic profile.

3. The system of claim 1, wherein the nozzle comprises a side disposed between the third end and the rectangular opening, the side having a trapezoidal profile.

4. The system of claim 1, wherein the nozzle is removably coupled to the second end of the second tube.

5. A system for applying an adhesive substance to an electronic device having a region designated to be coupled to another device, the region having a first shape defined by a first boundary, the system comprising:
a tube having an open end; and
a nozzle having an opening coupled to the open end of the tube, the opening having a second shape that is approximately the same as the first shape.

6. The system of claim 5, wherein the nozzle flares outwardly to form the opening, and wherein the nozzle comprises a top disposed opposite from the opening, and a side disposed between the top and the opening, the side having a profile that is approximately trapezoidal.

7. The system of claim 5, wherein the nozzle flares outwardly to form the opening, and wherein the nozzle comprises a top disposed opposite from the opening, and a side disposed between the top and the opening, the side having a profile that is approximately parabolic.

8. The system of claim 5, wherein the region has a first length and a first width, and wherein the opening has a second length that is 0.1 millimeter less than the first length.

9. The system of claim 5, wherein the nozzle further comprises an end positioned opposite from the opening and coupled to the open end of the tube, the end separated from the opening by a distance of between 120 micrometers to 130 micrometers.

10. The system of claim 5, wherein the opening is smaller than the region and is defined by a second boundary that, when positioned within the first boundary, is approximately 0.05 millimeter away from the first boundary.

11. The system of claim 5, wherein the region is a first region, and the nozzle further comprises an end having a second region positioned opposite from the opening and separated from the opening by a distance, and wherein the end is coupled to the open end of the tube, and further comprising a conduit coupling the open end of the tube and the end of the nozzle, the conduit having a cross sectional area that is smaller than the second region.

12. The system of claim 5, wherein the opening has a first area that is approximately five percent smaller than a second area of the region.

13. A method for coupling electronic devices, comprising:
providing an electronic device having a region to be coupled to another device using an adhesive substance, the region having a first shape;
forming a mound of the adhesive substance, the mound having a footprint, the footprint having a second shape that is approximately equal to the first shape; and
coupling the electronic device to a target area of a platform by positioning the mound over the target area and directly under the region of the electronic device.

14. The method of claim 13, wherein the region is approximately rectangular and includes a first length and a first width, and wherein forming a mound comprises forming a mound having an approximately rectangular footprint having a second length that is approximately 0.1 millimeter less than the first length.

15. The method of claim 13, wherein the region has a first diameter, and wherein forming a mound comprises forming a mound having a second diameter that is approximately 0.1 millimeter less than the first diameter.

16. The method of claim 13, wherein forming a mound comprises forming a mound having a height that is approximately 120 micrometers to 130 micrometers.

17. The method of claim 13, wherein forming a mound comprises forming a mound using a sole drop of the adhesive substance dispensed from an applicator nozzle having an outwardly flared opening and a height of approximately 120 micrometers to 130 micrometers.

18. The method of claim 13, wherein the electronic device is a die having a plurality of connectors and the platform is a substrate having a plurality of conductor tracks, and further comprising coupling the plurality of connectors to the conductor tracks using a wire bonding process after coupling the die to the target area of the substrate.

19. The method of claim 13, wherein the region is a first region, and the second shape of the footprint of the mound covers a second region that is smaller than the first region by approximately five percent.

20. The method of claim 13, wherein:
the electronic device is a die having a face and having an electronic circuitry;
the platform is a substrate;
the region of the die has an area that is at least 95 percent of the face of the die; and
forming a mound comprises forming only a single mound.
